(19) United States
(12) Patent Application Publication
(10) Pub. No.: US 2010/0327932 A1
(43) Pub. Date: Dec. 30, 2010

(54) FEEDBACK SYSTEM WITH IMPROVED STABILITY

(75) Inventors: Vladimir Aparin, San Diego, CA (US); Gary J. Ballantyne, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/492,541

(22) Filed: Jun. 26, 2009

(51) Int. Cl. H03H 11/16

(52) U.S. Cl. 327/254; 327/231

(57) ABSTRACT

Techniques for improving stability of a feedback system are described. In an exemplary design, the feedback system includes a forward path and a feedback path. The forward path receives an input signal and a rotated feedback signal and provides an output signal having a phase shift. The feedback path receives the output signal, generates a feedback signal, and rotates the feedback signal to obtain the rotated feedback signal having at least part of the phase shift removed. In another exemplary design, the feedback system includes a forward path and a feedback loop. The forward path receives a combined signal and provides an output signal having a phase shift. The feedback loop generates an error signal based on an input signal and the output signal, generates the combined signal based on the error signal and the input signal, and performs phase rotation to remove at least part of the phase shift.

### BACKGROUND

I. Field

The present disclosure relates generally to electronics, and more specifically to a feedback system for an electronics device.

II. Background

A circuit in an electronics device may be designed to perform a particular function such as amplification, filtering, frequency conversion, etc. It may be desirable for the circuit to have a linear function, so that an output signal is linearly related to an input signal. However, the circuit typically has some nonlinearity. The output signal would then include distortion components generated by the nonlinearity of the circuit. The distortion components may degrade performance. It may be desirable to mitigate the deleterious effects of the nonlinearity of the circuit in order to improve performance.

### BRIEF DESCRIPTION OF THE DRAWINGS

FIG. 1 shows a block diagram of a wireless communication device.

FIG. 2 shows a block diagram of a transmitter with Cartesian feedback.

FIGS. 3, 4 and 5 show block diagrams of three exemplary designs of a transmitter with Cartesian feedback and phase compensation to improve stability.

FIG. 6 shows a block diagram of a feedback system.

FIGS. 7A, 7B and 7C show block diagrams of three exemplary designs of a feedback system with phase compensation.

FIG. 8 shows a block diagram of a phase/gain compensator to improve stability.

FIG. 9 shows a block diagram of a transmitter system with feedback and phase compensation.

FIGS. 10 and 11 show two processes for generating an output signal with feedback and phase compensation.

### DETAILED DESCRIPTION

The word “exemplary” is used herein to mean “serving as an example, instance, or illustration.” Any design described herein as “exemplary” is not necessarily to be construed as preferred or advantageous over other designs.

A feedback system with improved stability is described herein. The feedback system may be used to mitigate nonlinearity of various types of circuit. The feedback system may also be used for various electronics devices such as wireless communication devices, cellular phones, personal digital assistants (PDAs), handheld devices, wireless modems, laptop computers, cordless phones, broadcast receivers, Bluetooth devices, consumer electronics devices, etc. For clarity, the use of the feedback system to improve linearity of a radio frequency (RF) transmitter in a wireless communication device is described below.

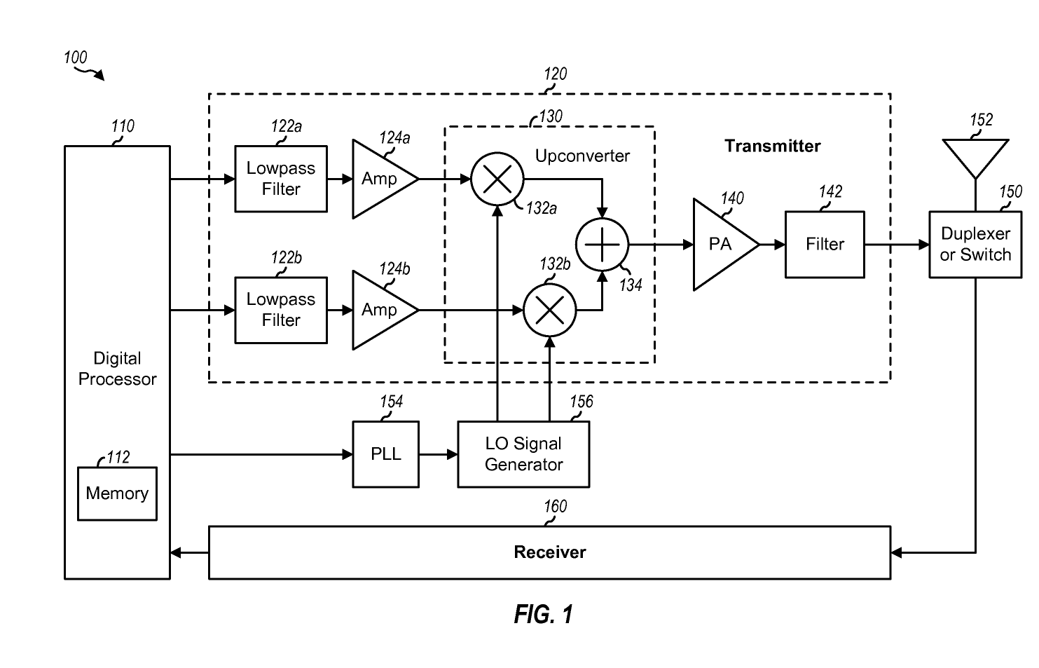

FIG. 1 shows a block diagram of an exemplary design of a wireless communication device 100, which may be a cellular phone or some other device. In the exemplary design shown in FIG. 1, wireless device 100 includes a digital processor 110, a transmitter 120, and a receiver 160 that support bi-directional communication. In general, wireless device 100 may include any number of transmitters and any number of receivers for any number of communication systems and any number of frequency bands.

A transmitter or a receiver may be implemented with a super-heterodyne architecture or a direct-conversion architecture. In the super-heterodyne architecture, a signal is frequency converted between baseband and RF in multiple stages, e.g., from baseband to an intermediate frequency (IF) in one stage, and then from IF to RF in another stage for a transmitter. In the direct-conversion architecture, a signal is frequency converted between baseband and RF in one stage. The super-heterodyne and direct-conversion architectures may use different circuit blocks and/or may have different requirements. In the exemplary design shown in FIG. 1, transmitter 120 is implemented with the direct-conversion architecture.

In the transmit path, digital processor 110 processes data to be transmitted and provides inphase (I) and quadrature (Q) baseband signals to transmitter 120. Within transmitter 120, lowpass filters 122a and 122b filter the I and Q baseband signals, respectively, to remove undesired images caused by the prior digital-to-analog conversion. Amplifiers (Amp) 124a and 124b amplify the signals from lowpass filters 122a and 122b, respectively, and provide I and Q amplified signals. An upconverter 130 receives the I and Q amplified signals and I and Q local oscillator (LO) signals from an LO signal generator 156. Within upconverter 130, a mixer 132a upconverts the I amplified signal with the I LO signal, a mixer 132b upconverts the Q amplified signal with the Q LO signal, and a summer 134 sums the outputs of mixers 132a and 132b and provides an upconverted signal. A power amplifier (PA) 140 amplifies the upconverted signal to obtain the desired output power level and provides an output RF signal. Power amplifier 140 may include a driver amplifier, one or more power amplifier stages, etc. A filter 142 filters the output RF signal to remove images caused by the frequency upconversion as well as noise in a receive frequency band and provides a transmit RF signal. The transmit RF signal is routed through a duplexer or switch 150 and transmitted via an antenna 152.

In the receive path, antenna 152 receives signals transmitted by base stations and/or other transmitter stations and provides an input RF signal, which is routed through duplexer or switch 150 and provided to receiver 160. Receiver 160 processes (e.g., amplifies, downconverts, and filters) the input RF signal and provides I and Q input baseband signals to digital processor 110. The details of receiver 160 are not shown in FIG. 1 for simplicity.

LO signal generator 156 generates the I and Q LO signals used by upconverter 130 for frequency upconversion. A phase locked loop (PLL) 154 receives timing information from digital processor 110 and generates control signals used to adjust the frequency and/or phase of the LO signals provided by LO signal generator 156.

FIG. 1 shows an exemplary design of a transmitter. In general, the conditioning of the signals in a transmitter may be performed by one or more stages of amplifier, filter, upconverter, etc. These circuit blocks may be arranged differently from the configuration shown in FIG. 1. Furthermore, other circuit blocks not shown in FIG. 1 may also be used to condition the signals in the transmitter. Some circuit blocks in FIG. 1 may also be omitted. All or a portion of transmitter 120 may be implemented on one or more analog integrated circuits (ICs), RF ICs (RFICs), mixed-signal ICs, etc.

Digital processor 110 may include various processing units for data transmission and reception and other functions. Memory 112 may store program codes and data for wireless device 100. Digital processor 110 and memory 112 may be implemented on one or more application specific integrated circuits (ASICs) and/or other ICs.

It is desirable for transmitter 120 to have a linear function so that the output RF signal is linearly related to the I and Q baseband signals. However, the circuits in transmitter 120 typically have some nonlinearity. For example, power amplifier 140, mixers 132a and 132b, amplifiers 124a and 124, and/or other circuits in transmitter 120 may have some nonlinearity. The nonlinearity may distort the output RF signal from transmitter 120 and may degrade performance.

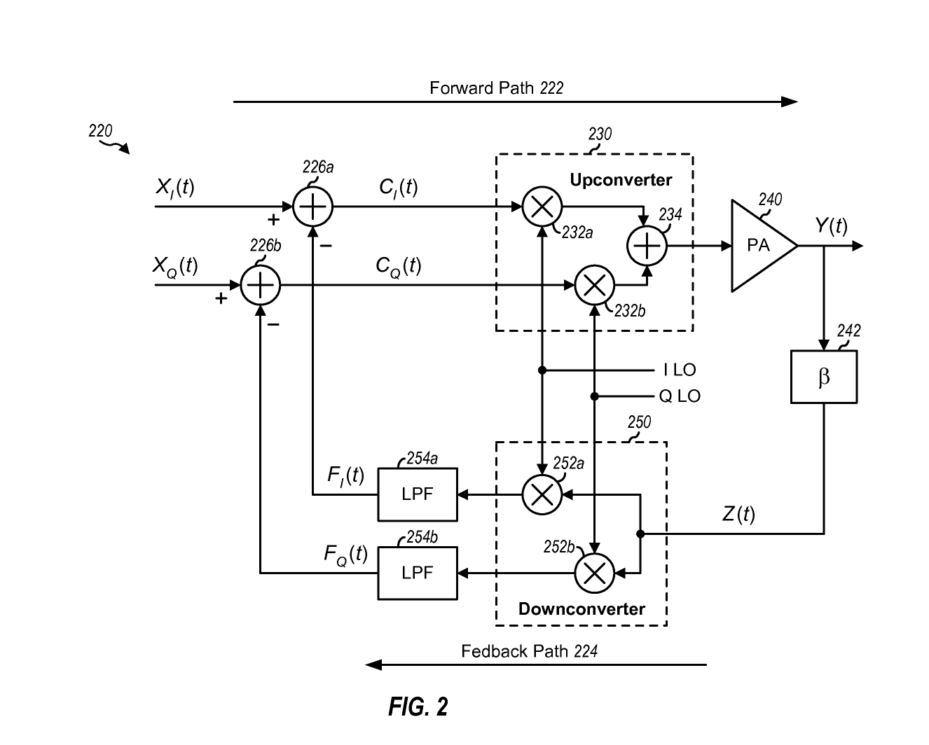

FIG. 2 shows a block diagram of a transmitter 220 with Cartesian feedback to improve linearity. Transmitter 220 receives an I input signal X_{I}(t) and a Q input signal X_{Q}(t) and provides an output RF signal Y(t). The I and Q input signals may correspond to the outputs of digital processor 110, the outputs of lowpass filters 122a and 122b, or the outputs of amplifiers 124a and 124b in FIG. 1. Transmitter 220 includes a forward path 222 and a feedback path 224. Forward path 222 includes summers 226a and 226b, an upconverter 230, and a power amplifier 240. Feedback path 224 includes a feedback circuit 242, a downconverter 250, and lowpass filters 254a and 254b.

In forward path 222, summer 226a receives and subtracts an I feedback signal F_{I}(t) from the I input signal and provides an I compensated signal C_{I}(t) to upconverter 230. Similarly, summer 226b receives and subtracts a Q feedback signal F_{Q}(t) from the Q input signal and provides a Q compensated signal C_{Q} (t) to upconverter 230. Within upconverter 230, a mixer 232a upconverts the I compensated signal with an I LO signal, a mixer 232b upconverts the Q compensated signal with a Q LO signal, and a summer 234 sums the outputs of mixers 232a and 232b and provides an upconverted signal. Power amplifier 240 amplifies the upconverted signal and provides the output RF signal.

In feedback path 224, feedback circuit 242 provides a portion of the output RF signal from power amplifier 240 as a feedback RF signal Z(t) to downconverter 250. Feedback circuit 242 has a gain of β, which is less than one. The feedback RF signal is thus an attenuated version of the output RF signal. Within downconverter 250, a mixer 252a downconverts the feedback RF signal with the I LO signal used for upconverter 230, and mixer 252b downconverts the feedback RF signal with the Q LO signal used for upconverter 230. The outputs of mixers 252a and 252b include signal components at the sum and difference frequencies. Lowpass filter 254a filters the output of mixer 252a to attenuate the signal component at the sum frequency and provides the I feedback signal comprising mostly the signal component at the difference frequency. Similarly, lowpass filter 254b filters the output of mixer 252b and provides the Q feedback signal.

When the feedback loop is closed, as shown in FIG. 2, a portion of the output RF signal is fed back, downconverted, and subtracted from the I and Q input signals. The I and Q feedback signals include a desired signal component as well as distortion components. The feedback reduces the desired signal component in the forward path but reduces the distortion components even faster. Hence, transmitter 220 is more linear with feedback than a transmitter without feedback.

The feedback in transmitter 220 is referred to as Cartesian feedback since I and Q feedback components in Cartesian coordinate are subtracted from I and Q signal components in the forward path. Ideally, the I feedback component should be aligned in phase with the I signal component, and the Q feedback component should be aligned in phase with the Q signal component. However, in a practical implementation, delays of upconverter 230, power amplifier 240, and/or other effects may result in a phase shift of φ in the output RF signal. The phase shift may also be referred to as an RF phase shift, a phase rotation, a phase offset, a delay, etc. The phase shift may be relatively large and may also be unknown or difficult to characterize, e.g., due to the presence of circuits such as RF resonators having a sharp phase transition at the resonant frequency.

The output RF signal with the phase shift may be expressed as:

Y(t)=A·[X_{I}(t)·cos(ωt+φ)+X_{Q}(t)·sin(ωt+φ)], Eq (1)

where A is the gain of upconverter 230 and power amplifier 240,

ω is the frequency of the I and Q LO signals, and

cos(ωt) is the I LO signal and sin(ωt) is the Q LO signal.

The phase shift may affect the stability of the feedback system. In particular, as the phase shift approaches π/2 or 180°, the feedback becomes positive, and the loop becomes unstable. It is thus desirable to account for the phase shift in order to improve the stability of the feedback system.

In an aspect, phase shift compensation may be applied in a feedback path of a feedback system to improve stability and possibly obtain other benefits. The phase shift compensation may attempt to correct for the phase shift so that the I and Q feedback components are approximately aligned in phase with the I and Q signal components, respectively.

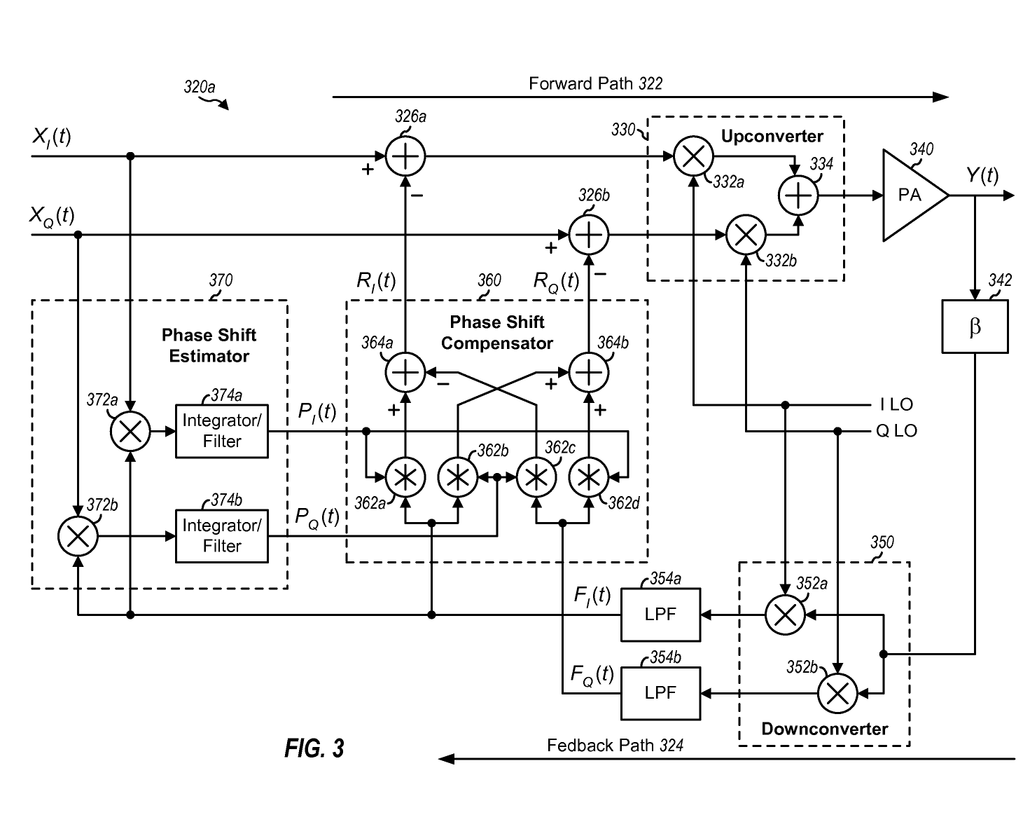

FIG. 3 shows a block diagram of an exemplary design of a transmitter 320a with Cartesian feedback to improve linearity and phase compensation to improve stability. Transmitter 320a includes a forward path 322 and a feedback path 324. Forward path 322 includes summers 326a and 326b, an upconverter 330 comprising mixers 332a and 332b and a summer 334, and a power amplifier 340, which are coupled in a similar manner as summers 226a and 226b, upconverter 230, and power amplifier 240 in FIG. 2. Feedback path 324 includes a feedback circuit 342, a downconverter 350 comprising mixers 352a and 352b, and lowpass filters 354a and 354b, which are coupled in a similar manner as feedback circuit 242, downconverter 250, and lowpass filters 254a and 254b in FIG. 2. Feedback path 324 further includes a phase shift compensator 360.

Phase shift compensator 360 receives the I and Q feedback signals from lowpass filters 354a and 354b, rotates the I and Q feedback signals to compensate for the phase shift in the forward path, and provides an I rotated feedback signal R_{I}(t) and a Q rotated feedback signal R_{Q} (t). Summer 326a subtracts the I rotated feedback signal from an I input signal and provides an I compensated signal to upconverter 330. Similarly, summer 326b subtracts the Q rotated feedback signal from a Q input signal and provides a Q compensated signal to upconverter 330. A phase shift estimator 370 receives the I and Q input signals and the I feedback signal, estimates the phase shift based on the received signals, and provides an I phase estimate signal P_{I}(t) and a Q phase estimate signal P_{Q} (t). Phase shift estimator 370 estimates the phase shift by using the I and Q input signals as a phase reference. The I and Q phase estimate signals comprise I and Q components of the phase shift, as described below.

In the exemplary design shown in FIG. 3, phase shift compensator 360 includes four real multipliers 362a, 362b, 362c and 362d and two real summers 364a and 364b. Multipliers 362a and 362b multiply the I feedback signal with the I and Q phase estimate signals, respectively. Multipliers 362c and 362d multiply the Q feedback signal with the Q and I phase estimate signals, respectively. Summer 364a subtracts the output of multiplier 362c from the output of multiplier 362a and provides the I rotated feedback signal. Summer 364b sums the outputs of multipliers 362b and 362d and provides the Q rotated feedback signal.

In the exemplary design shown in FIG. 3, phase shift estimator 370 includes mixers 372a and 372b and integrators/filters 374a and 374b. Mixers 372a and 372b mix the I feedback signal with the I and Q input signals, respectively. Mixers 372a and 372b may also be implemented with multipliers or some other circuits. Integrator/filter 374a integrates or filters the output of mixer 372a and provides the I phase estimate signal. Similarly, integrator/filter 374b integrates or filters the output of mixer 372b and provides the Q phase estimate signal. Integrators/filters 374a and 374b attenuate high frequency components and pass low frequency components (ideally, pass only DC component).

The I and Q feedback signals from lowpass filters 354a and 354b may be expressed as:

$$\begin{matrix}{F}_{I} ( t ) = \frac{A \cdot β}{2} [ {X}_{I} ( t ) \cdot cos ( φ ) + {X}_{Q} ( t ) \cdot sin ( φ ) ] , and & Eq ( 2 ) \\ {F}_{Q} ( t ) = \frac{A \cdot β}{2} [ - {X}_{I} ( t ) \cdot sin ( φ ) + {X}_{Q} ( t ) \cdot cos ( φ ) ] . & Eq ( 3 )\end{matrix}$$

Equations (2) and (3) assume that the signal component at the sum frequency is removed by lowpass filters 354. For simplicity, much of the description herein assumes no estimation error, and equal signs (instead of approximate signs) are used in most of the equations herein.

Within phase shift estimator 370, an M_{I}(t) signal from mixer 372a and an M_{Q} (t) signal from mixer 372b may be expressed as:

$$\begin{matrix}\begin{matrix}{M}_{I} ( t ) = \frac{A \cdot β}{2} [ {X}_{I} ( t ) \cdot cos ( φ ) + {X}_{Q} ( t ) \cdot sin ( φ ) ] \cdot {X}_{I} ( t ) \\ = \frac{A \cdot β}{2} [ {X}_{I}^{2} ( t ) \cdot cos ( φ ) + {X}_{I} ( t ) \cdot {X}_{Q} ( t ) \cdot sin ( φ ) ]\end{matrix} & Eq ( 4 ) \\ \begin{matrix}{M}_{Q} ( t ) = \frac{A \cdot β}{2} [ {X}_{I} ( t ) \cdot cos ( φ ) + {X}_{Q} ( t ) \cdot sin ( φ ) ] \cdot {X}_{Q} ( t ) \\ = \frac{A \cdot β}{2} [ {X}_{I} ( t ) \cdot {X}_{Q} ( t ) \cdot cos ( φ ) + {X}_{Q}^{2} ( t ) \cdot sin ( φ ) ] .\end{matrix} & Eq ( 5 )\end{matrix}$$

The I and Q input signals may be assumed to be uncorrelated. Integrator/filter 374a filters the cross product component X_{I}(t)·X_{Q}(t)·sin(φ) in the signal from mixer 372a and provides the desired component X_{I}²(t)·cos(φ). Similarly, integrator/filter 374b filters the cross product component X_{I}(t)·X_{Q}(t)·cos(φ) in the signal from mixer 372b and provides the desired component X_{Q}²(t)·sin(φ). The I and Q phase estimate signals from integrators/filters 374a and 374b may then be expressed as:

P_{I}(t)=K·cos(φ), and Eq (6)

P_{Q}(t)=K·sin(φ), Eq (7)

where K=A·β·G/2 and G=avg {X_{I}² (t)}=avg {X_{Q}²(t)}.

As shown in equations (6) and (7), the I and Q phase estimate signals are indicative of the phase shift φ. Phase shift compensator 360 is a complex multiplier that rotates a complex feedback signal comprising the F_{I}(t) and F_{Q} (t) signals by the phase shift φ and provides a complex rotated feedback signal comprising the R_{I}(t) and R_{Q}(t) signals. The I and Q rotated feedback signals may be expressed as:

$$\begin{matrix}{R}_{I} ( t ) = \frac{A \cdot β \cdot K}{2} \cdot {X}_{I} ( t ) , and & Eq ( 8 ) \\ {R}_{Q} ( t ) = \frac{A \cdot β \cdot K}{2} \cdot {X}_{Q} ( t ) . & Eq ( 9 )\end{matrix}$$

As shown in equations (8) and (9), the I and Q rotated feedback signals may be scaled versions of the I and Q input signals, respectively, if the estimate of the phase shift is reasonably accurate. The phase shift compensation may thus remove or reduce the phase shift so that stability of the Cartesian feedback system may be improved.

As noted above, mixers 372a and 372b within phase shift estimator 370 may be implemented with mixers or multipliers since only the relative phase between the I feedback signal and the I and Q input signals is of interest. Multipliers 362a to 362d within phase shift compensator 360 should be implemented with multipliers (and not mixers) since (i) the amplitude of the I and Q feedback signals carries the desired amplitude in the I and Q rotated feedback signals and (ii) the amplitude of the I and Q phase estimate signals carries the desired phase shift information.

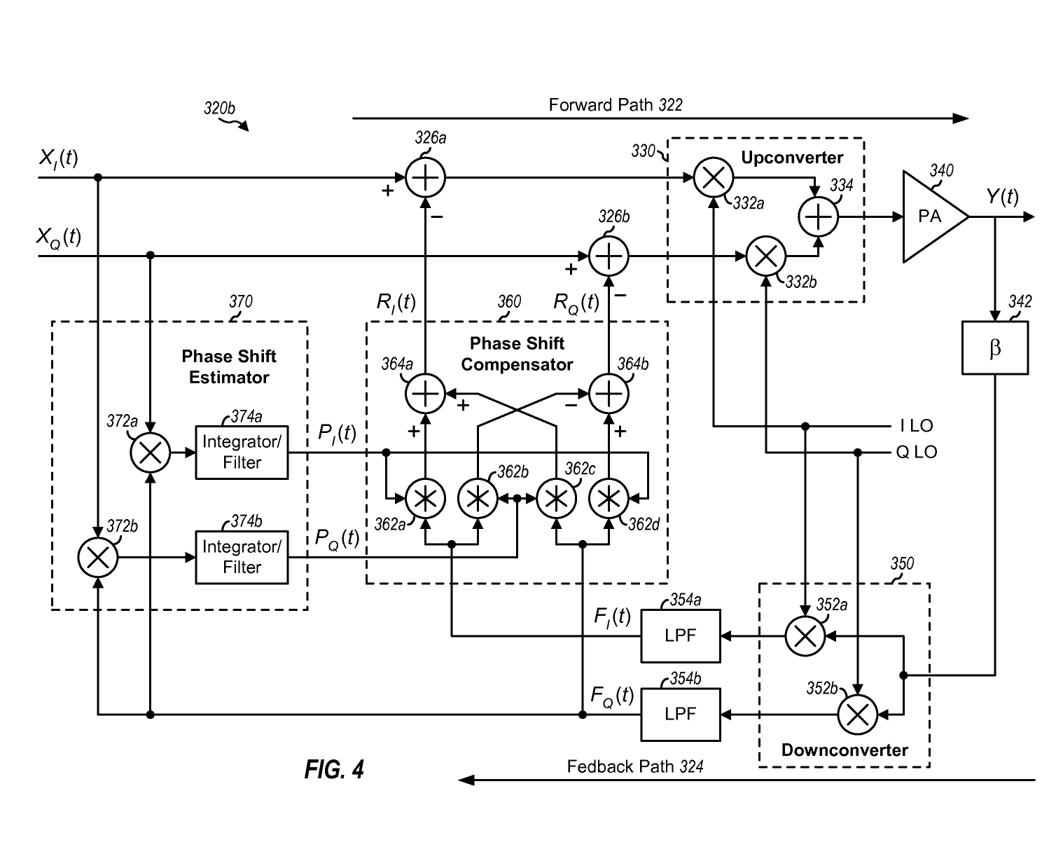

FIG. 4 shows a block diagram of an exemplary design of a transmitter 320b with Cartesian feedback to improve linearity and phase compensation to improve stability. Transmitter 320b includes all of the circuit components in transmitter 320a in FIG. 3, which are coupled as described above except for the following differences. First, the Q feedback signal (instead of the I feedback signal) is provided to phase shift estimator 370, and the Q and I input signals (instead of the I and Q input signals) are provided to mixers 372a and 372b, respectively. This results in integrator/filter 374a providing the I phase estimate signal, P_{I}(t)=K·cos(φ), and integrator/filter 374b providing an inverted Q phase estimate signal, P_{Q}(t)=−K·sin(φ). Phase shift estimator 370 thus provides different I and Q phase estimate signals due to the use of the Q feedback signal instead of the I feedback signal. Second, within phase shift compensator 360, summer 364a sums the outputs of multipliers 362a and 362c, and summer 364b subtracts the output of multiplier 362b from the output of multiplier 364d. The signal subtraction is thus moved from summer 364a to summer 364b due to the inverted Q phase estimate signal from integrator/filter 374b in phase shift estimator 370.

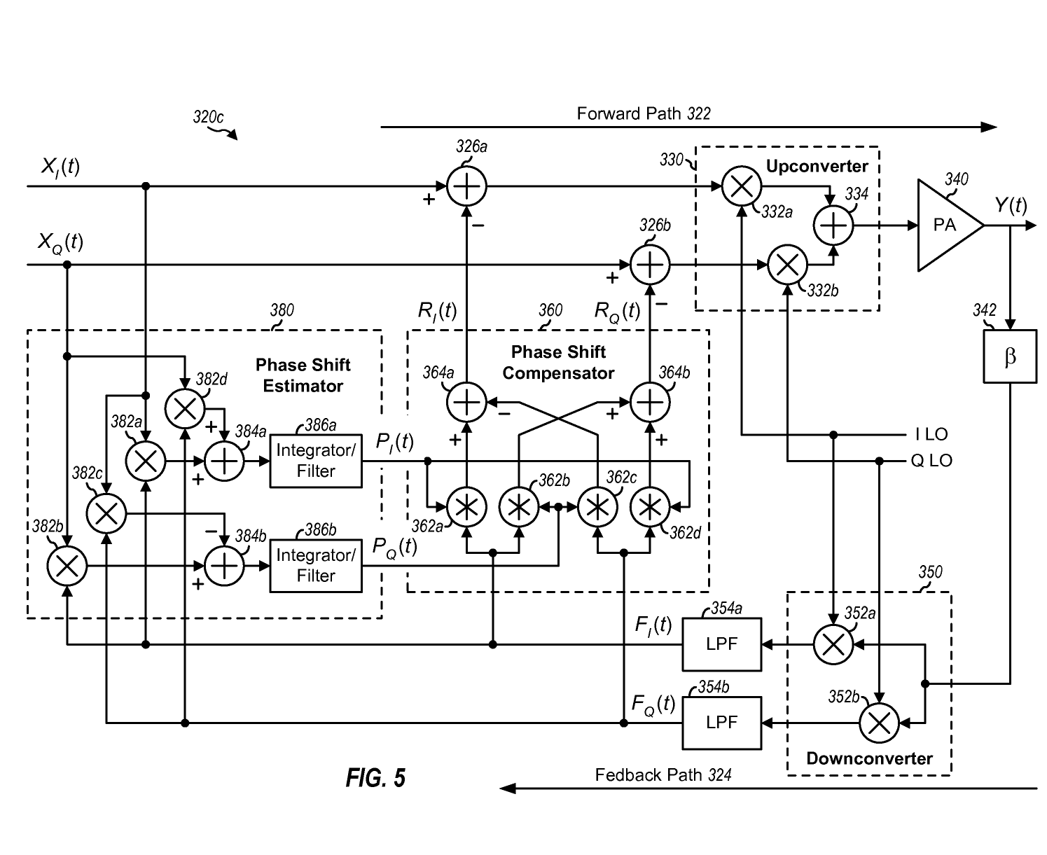

FIG. 5 shows a block diagram of an exemplary design of a transmitter 320c with Cartesian feedback to improve linearity and phase compensation to improve stability. Transmitter 320c includes all of the circuit components in transmitter 320a in FIG. 3 except for phase shift estimator 370, which is replaced by a phase shift estimator 380.

Within phase shift estimator 380, mixers 382a and 382b mix the I feedback signal with the I and Q input signals, respectively. Mixers 382c and 382d mix the Q feedback signal with the I and Q input signals, respectively. A summer 384a sums the outputs of mixers 382a and 382d. A summer 384b subtracts the output of mixer 382c from the output of mixer 382b. An integrator/filter 386a integrates or filters the output of summer 384a and provides the I phase estimate signal. Similarly, an integrator/filter 386b integrates or filters the output of summer 384b and provides the Q phase estimate signal. Mixers 382a to 382d may also be implemented with multipliers or some other circuits.

Phase shift estimator 380 includes mixers 382a and 382b that provide the I and Q signals shown in equations (4) and (5). Phase shift estimator 380 further includes mixers 382c and 382d that provide I and Q signals comprising inverted cross product components. Summer 384a cancels the cross product component X_{I}(t)·X_{Q}(t)·sin(φ) from mixers 382a and 382d and provides the desired component. Similarly, summer 384b cancels the cross product component X_{I}(t)·X_{Q}(t)·cos(φ) from mixers 382b and 382c and provides the desired component. An S_{I}(t) signal from summer 384a and an S_{Q}(t) signal from summer 384b may be expressed as:

$$\begin{matrix}{S}_{I} ( t ) = \frac{A \cdot β}{2} [ {X}_{I}^{2} ( t ) + {X}_{Q}^{2} ( t ) ] \cdot cos ( φ ) , and & Eq ( 10 ) \\ {S}_{Q} ( t ) = \frac{A \cdot β}{2} [ {X}_{I}^{2} ( t ) + {X}_{Q}^{2} ( t ) ] \cdot sin ( φ ) . & Eq ( 11 )\end{matrix}$$

As shown in equations (10) and (11), the S_{I}(t) and S_{Q} (t) signals from summers 384a and 384b include only the desired components, with the cross product components being canceled. Canceling the cross product components may improve the estimate of the phase shift, especially when the I and Q input signals are not totally uncorrelated.

FIGS. 3, 4 and 5 show three exemplary designs of estimating the phase shift in a feedback system. The phase shift may also be estimated in other manners. The phase shift estimate and compensation may be performed in digital domain (e.g., with fixed or floating point arithmetic) or in analog domain (e.g., with analog circuits). For a digital implementation, the number of bits for one or more variables may be limited in order to reduce computational complexity. For both digital and analog implementations, a single bit may be used to represent the sign (e.g., + or −) of a given signal.

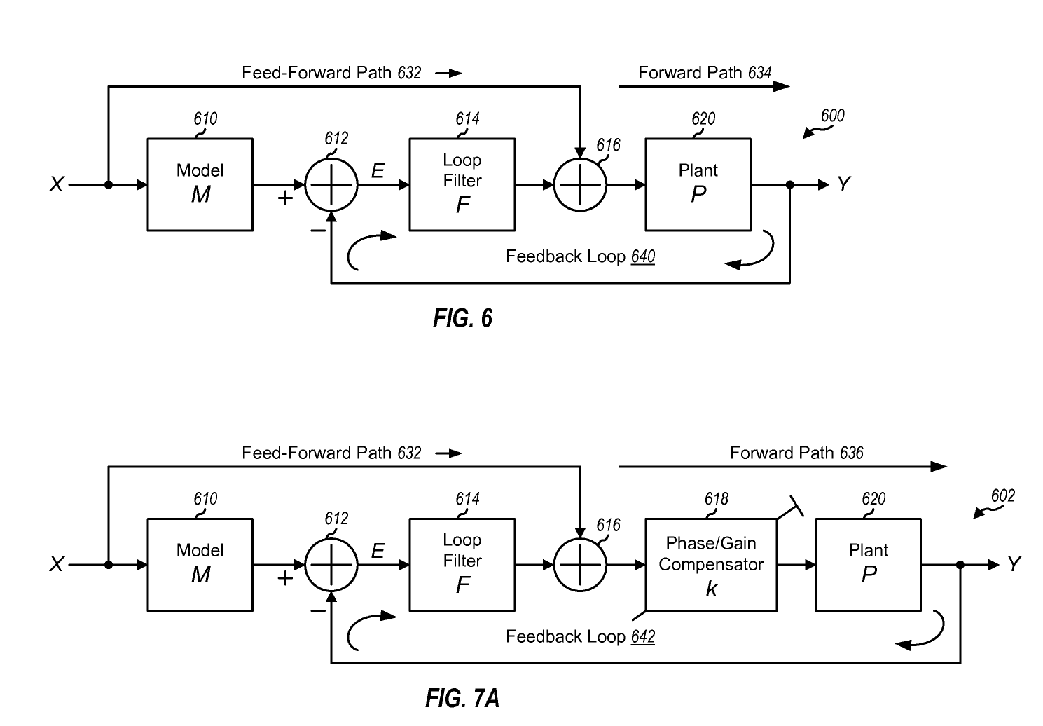

FIG. 6 shows a block diagram of an exemplary design of a feedback system 600 with feedback to mitigate nonlinearity of a plant 620. Plant 620 may be any circuit having nonlinearity to be mitigated, e.g., a power amplifier, a transmitter, etc. Within system 600, an input signal (denoted as X) is provided to both a model 610 and a summer 616. Model 610 processes the input signal with a transfer function M, which may be set to obtain the desired output as described below, and provides a target signal. A summer 612 subtracts an output signal provided by plant 620 from the target signal provided by model 610 and outputs an error signal (denoted as E). A loop filter 614 filters the error signal with a transfer function F and provides a filtered error signal. Loop filter 614 may be a lowpass filter having a bandwidth that may be selected to provide the desired closed-loop characteristics. Summer 616 sums the input signal with the filtered error signal and provides a combined signal. Plant 620 processes the combined signal with a transfer function P and provides the output signal (denoted as Y). The various signals in FIG. 6 may be complex signals, with each complex signal comprising both I and Q components.

System 600 includes a feed-forward path 632 from the input signal to summer 616. System 600 also includes a forward path 634 from the combined signal to the output signal. Forward path 634 includes only plant 620 in FIG. 6. System 600 further includes a feedback loop 640, which is formed from the output signal Y through summer 612, loop filter 614, summer 616, and plant 620. Feedback loop 640 thus includes forward path 634. System 600 is configured so that plant 620 is driven with a combination of the input signal and the error signal.

A transfer function for system 600 may be expressed as:

$$\frac{Y}{X} = P ( \frac{1 + FM}{1 + FP} ) . \qquad Eq ( 12 )$$

As shown in equation (12), the desired transfer function for system 600 and the desired closed-loop characteristics of feedback loop 640 may be obtained by selecting the proper transfer function F for loop filter 614 and the proper transfer function M for model 610.

System 600 may implement Cartesian feedback to linearize an RF transmitter or a power amplifier represented by plant 620. As discussed above, a problem with Cartesian feedback is that phase shift due to plant 620 may cause coupling between the I and Q components, which may then reduce stability margins and may eventually lead to instability. The phase shift may be adaptively estimated and corrected as described below.

An advantage of the structure shown in FIG. 6 is an explicit model 610 of plant 620. If the transfer function of model 610 is equal to the transfer function of plant 620 (i.e., if M=P), then there is no feedback and the system output will follow the model output, or Y=P X. FIG. 6 thus shows an example of model reference control. The tools available from Model Reference Adaptive Control (MRAC) (extended to cope with complex variables) may then be used to solve the phase shift problem in system 600.

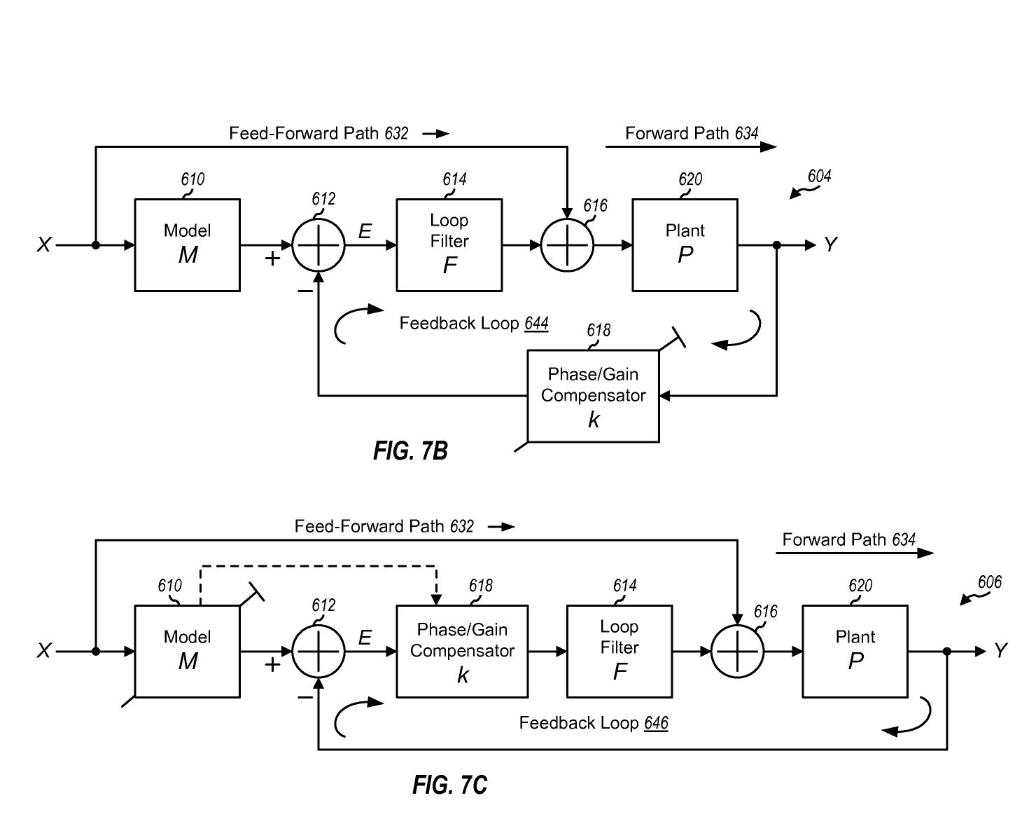

FIG. 7A shows a block diagram of an exemplary design of a feedback system 602 with feedback to mitigate nonlinearity of plant 620 and phase compensation to improve stability. Feedback system 602 includes all of blocks 610 through 620 in feedback system 600 in FIG. 6. Feedback system 602 further includes a phase/gain compensator 618 coupled between summer 616 and plant 620. Phase/gain compensator 618 receives the combined signal from summer 616, multiplies the combined signal with a complex value k, and provides a compensated signal having the phase shift corrected. In one exemplary design, the complex value may have unit magnitude. Phase/gain compensator 618 may then perform only phase compensation and may simply rotate the phase of the combined signal. In another exemplary design, the complex value may have a variable amplitude. Phase/gain compensator 618 may then perform both gain and phase compensation and may adjust the amplitude as well as the phase of the combined signal. In any case, plant 620 processes the compensated signal with transfer function P and provides the output signal. The other blocks within feedback system 602 operate as described above for FIGS. 6 and 7A.

System 602 includes feed-forward path 632 from the input signal to summer 616. System 602 also includes a forward path 636 that includes phase/gain compensator 618 and plant 620. System 600 further includes a feedback loop 642, which is formed from the output signal Y through summer 612, loop filter 614, summer 616, phase/gain compensator 618, and plant 620. Feedback loop 642 thus includes forward path 636.

FIG. 7B shows a block diagram of an exemplary design of a feedback system 604 with feedback to mitigate nonlinearity of plant 620 and phase compensation to improve stability. Feedback system 604 includes all of blocks 610 through 620 in feedback system 602 in FIG. 7A. However, phase/gain compensator 618 is placed in the feedback path between plant 620 and summer 612. Phase/gain compensator 618 receives the output signal from plant 620 and provides a compensated signal. Summer 612 subtracts the compensated signal from the target signal provided by model 610 and outputs the error signal. The other blocks within feedback system 604 operate as described above for FIG. 6.

System 604 includes feed-forward path 632 and forward path 634. System 604 further includes a feedback loop 644, which is formed from the output signal Y through phase/gain compensator 618, summer 612, loop filter 614, summer 616, and plant 620. Feedback loop 642 thus includes forward path 634.

In general, phase/gain compensator 618 may be placed anywhere within the feedback loop. The placement of phase/gain compensator 618 may be dependent on various considerations such as implementation complexity, performance, etc.

FIGS. 7A and 7B show two exemplary designs of a direct approach for a feedback system. In the direct approach, a given block may estimate a parameter for a plant and then apply the parameter.

FIG. 7C shows a block diagram of an exemplary design of a feedback system 606 with feedback to mitigate nonlinearity of plant 620 and phase compensation to improve stability. Feedback system 606 utilizes an indirect approach in which one block estimates a parameter for plant 620 and another block applies the parameter. Feedback system 606 includes all of blocks 610 through 620 in feedback system 602 in FIG. 7A, with the following differences. Phase/gain compensator 618 is coupled between summer 612 and loop filter 614 in FIG. 7C but may also be placed at other locations within the feedback loop. Model 610 adaptively determines a complex value k and provides the complex value to phase/gain compensator 618. Phase/gain compensator 618 receives the error signal from summer 612, multiplies the error signal with the complex value, and provides a compensated signal to loop filter 614.

System 606 includes feed-forward path 632 and forward path 634. System 606 further includes a feedback loop 646, which is formed from the output signal Y through summer 612, phase/gain compensator 618, loop filter 614, summer 616, and plant 620. Feedback loop 646 thus includes forward path 634.

For the exemplary designs shown in FIGS. 7A to 7C, the complex value k may be used to correct for phase shift due to plant 620 and/or other blocks in the feedback system. It may be desirable to automatically determine the complex value based on the available signals.

In one exemplary design, the complex value k may be adaptively determined based on the error signal E from summer 612 and the input signal X, as follows:

$$\begin{matrix}\frac{d k}{d t} = γ {X}^{*} E , and & Eq ( 13 ) \\ k = \int γ {X}^{*} E , & Eq ( 14 )\end{matrix}$$

where γ is an adaptation factor that determines the rate of convergence of the complex value k to a final value, and “*” denotes a complex conjugate.

In the exemplary design shown in equation (14), the complex value k may be obtained by computing the product of the complex conjugate of the input signal X and the error signal E, scaling the product with the adaptation factor, and integrating the scaled product. A condition for stability of the adaptive algorithm is that the transfer function P/(1+F P) is strictly positive real (SPR).

In another exemplary design, the complex value k may be adaptively determined based on the error signal E from summer 612 and the output signal Y from plant 620, as follows:

$$\begin{matrix}\frac{d k}{d t} = γ {Y}^{*} E , and & Eq ( 15 ) \\ k = \int γ {Y}^{*} E . & Eq ( 16 )\end{matrix}$$

The exemplary designs shown in equations (14) and (16) have similar form, with equation (14) using the input signal X and equation (16) using the output signal Y. It can be shown that adaptive algorithms using equations (14) and (16) can converge to a complex value having a phase that is equal to but opposite of the phase shift of the plant.

The complex value k may also be estimated with various other adaptive algorithms known in the art. Furthermore, variations of these adaptive algorithms may also be used. For example, integration may be performed with respect to a positive-definite kernel. An example of a positive-definite kernel is exp(−α·t), with α>0. This kernel may replace integration with 1/(s+α).

The adaptation to obtain the complex value k may be performed in digital domain (e.g., with fixed or floating point arithmetic) or in analog domain (e.g., with analog circuits). For a digital implementation, the number of bits for one or more variables may be limited in order to reduce computational complexity. For example, the error signal, the input signal, and/or the output signal may be limited to a predetermined number of bits. For both digital and analog implementations, a single bit may be used to represent the sign (e.g., + or −) of a given signal, e.g., the input signal or the output signal. In general, a limited number of bits may be used for one or both of the two signals (e.g., E and X, or E and Y) used to derive the complex value.

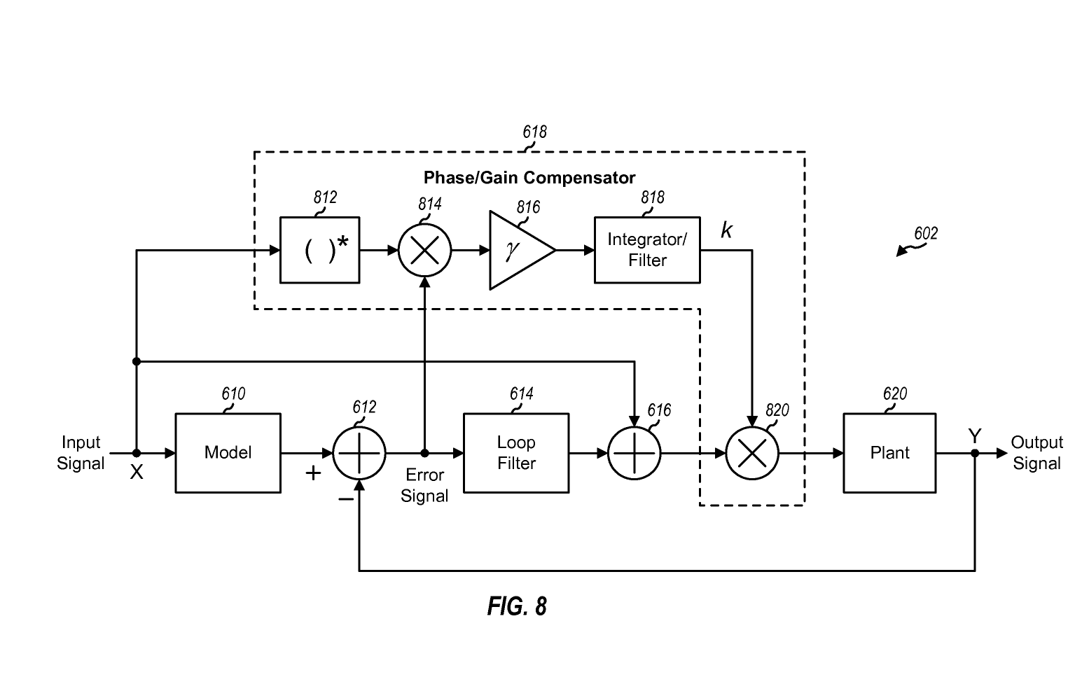

FIG. 8 shows a block diagram of an exemplary design of phase/gain compensator 618 in FIG. 7A based on the adaptive algorithm shown in equation (14). Within phase/gain compensator 618, a unit 812 receives the input signal and provides the complex conjugate of the input signal. A multiplier 814 multiplies the output of unit 812 with the error signal from summer 612. In another exemplary design, the error signal may be filtered before being applied to multiplier 814. In any case, a gain element 816 scales the output of multiplier 814 with the adaptation factor γ. An integrator/filter 818 integrates or filters the output of gain element 816 (e.g., separately for the I and Q components) and provides the complex value k. In general, any suitable filter function may be used for integrator/filter 818.

In the forward path, a complex multiplier 820 is coupled between summer 616 and plant 620. Complex multiplier 820 multiplies the combined signal from summer 616 with the complex value k to rotate the phase of the combined signal and possibly adjust the amplitude of the combined signal. Complex multiplier 820 provides the compensated signal to plant 620.

An adaptive algorithm to determine the complex value k can converge if the feedback loop is initially stable. In one exemplary design, initial stability may be ensured based on some prior knowledge of the phase shift of plant 620. This prior knowledge of the phase shift may be obtained from factory calibration, from the phase obtained from the last time the algorithm was operated, from a phase measured in an open loop manner, etc. An initial phase corresponding to the prior knowledge of the phase shift may be applied at the output of integrator/filter 818. In another exemplary design, different initial phase values may be applied, one value at a time, until a converged complex value k is detected. This exemplary design may be used for the very first time that the algorithm is executed. The phase from the converged complex value may be stored for use the next time the algorithm is executed.

In an exemplary design, a desired transfer function (e.g., a desired gain) for plant 620 may be applied to model 610. The adaptive algorithm may then be operated to determine the complex value k. In another exemplary design, model 610 may be omitted by using a transfer function of 1.

In one exemplary design, the entire complex value is applied in the feedback loop, e.g., with a complex multiplier as shown in FIG. 8. In this case, the phase shift as well as the magnitude of plant 620 may be corrected by the complex value to obtain the desired transfer function in model 610. This exemplary design may be used to adjust the transmit power of plant 620 and implement power control by varying the desired gain in model 620. In a transmitter, the phase correction may be applied via a quadrature modulator, and the amplitude correction may be applied via a variable gain amplifier (VGA). In another exemplary design, only the argument (or phase) of the complex value is applied in the feedback loop, e.g., with a phase shifter. In this case, only the phase shift may be corrected by the complex value.

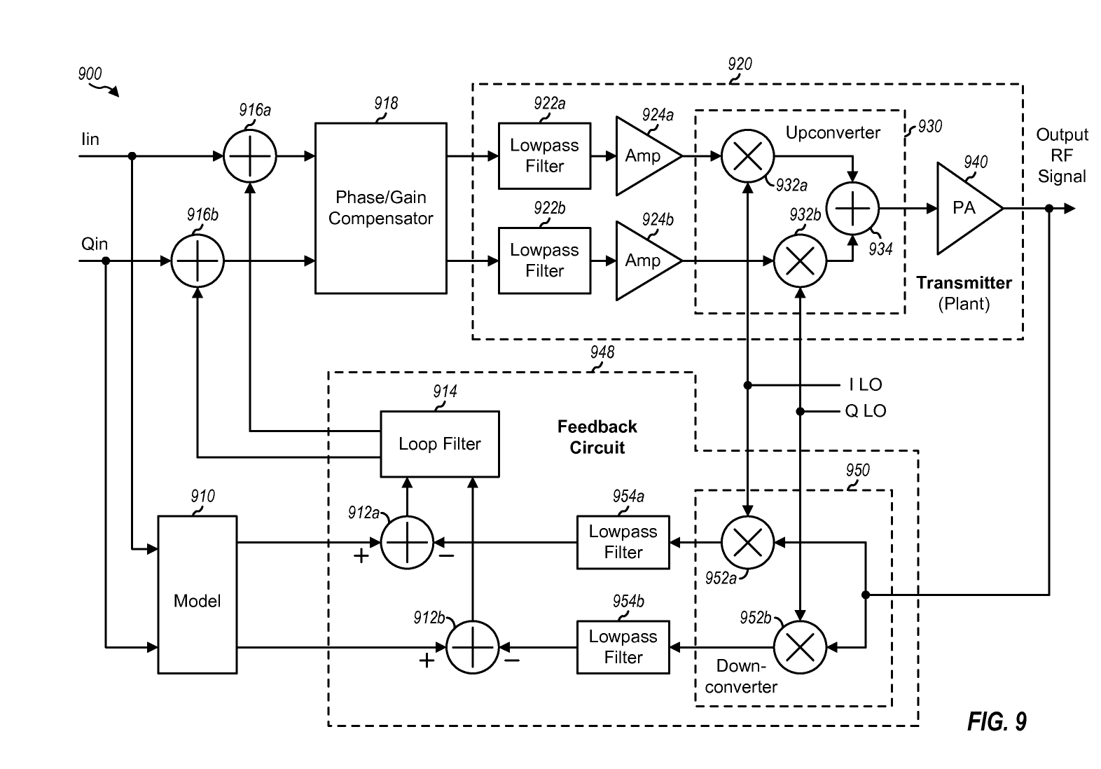

FIG. 9 shows a block diagram of an exemplary design of a transmitter system 900 with feedback to mitigate nonlinearity of a transmitter 920 and phase compensation to improve stability. Transmitter 920 has nonlinearity to be mitigated and may correspond to plant 620 in FIGS. 7A, 7B and 7C. Transmitter 920 includes lowpass filters 922a and 922b, amplifiers 924a and 924b, an upconverter 930 comprising mixers 932a and 932b and a summer 934, and a power amplifier 940, which may operate as described above for corresponding circuit blocks 122 through 140 within transmitter 120 in FIG. 1. Transmitter system 900 further includes other circuit blocks to implement feedback and phase compensation.

In the feed-forward path, an I baseband signal (fin) and a Q baseband signal (Qin) are provided summers 916a and 916b, respectively. Summer 916a sums the I baseband signal and an I filtered error signal from a loop filter 914 and provides an I combined signal. Similarly, a summer 916b sums the Q baseband signal and a Q filtered error signal from loop filter 914 and provides a Q combined signal. Loop filter 914 may correspond to loop filter 614 in FIGS. 7A to 7C, and real summers 916a and 916b may correspond to complex summer 616 in FIG. 7A to 7C. A phase/gain compensator 918 receives the I and Q combined signals, estimates and applies a complex value k, and provides I and Q compensated signal to transmitter 920. Phase/gain compensator 918 may be implemented as described above for phase/gain compensator 618 in FIG. 8.

In the feedback path, a feedback circuit 948 receives I and Q target signals from a model 910 and the output RF signal and generates the I and Q filtered error signals. Feedback circuit 948 includes real summers 912a and 912b, loop filter 914, and a downconverter 950. Within feedback circuit 948, the output RF signal from power amplifier 940 is downconverted from RF to baseband by downconverter 950. Within downconverter 950, the output RF signal is downconverted by a mixer 952a with the I LO signal and further filtered by a lowpass filter 954a to obtain an I feedback signal. The output RF signal is also downconverted by a mixer 952b with the Q LO signal and further filtered by a lowpass filter 954b to obtain a Q feedback signal. The I and Q LO signals used for upconverter 930 are also used for downconverter 950 (possibly with buffering not shown in FIG. 9). Summer 912a subtracts the I feedback signal from the I target signal from model 910 and provides an I error signal to loop filter 914. Summer 912b subtracts the Q feedback signal from the Q target signal from model 910 and provides a Q error signal to loop filter 914. Real summers 912a and 912b may correspond to complex summer 612 in FIGS. 7A to 7C. Loop filter 914 may correspond to loop filter 614 in FIGS. 7A to 7C. Model 910 may correspond to model 610 in FIGS. 7A to 7C.

FIG. 9 shows an exemplary design of mitigating nonlinearity of transmitter 920 with feedback and phase compensation. Feedback and phase compensation may also be used for other circuits in the transmitter. For example, feedback and phase compensation may be used for (i) only power amplifier 940, or (ii) a combination of upconverter 930, power amplifier 940, and filter 942, or (iii) a combination of amplifiers 924, upconverter 930, power amplifier 940, and filter 942, or (iv) some other combination of circuits.

In an exemplary design, an apparatus (e.g., a wireless device, an IC, etc.) may comprise a feedback system that may include a forward path and a feedback path, e.g., as shown in FIGS. 3 to 5. The forward path may comprise at least one first circuit that receives an input signal and a rotated feedback signal and provides an output signal having a phase shift due to delay of one or more circuits. The feedback path may comprise at least one second circuit that receives the output signal, generates a feedback signal, and rotates the feedback signal to obtain the rotated feedback signal having at least part of the phase shift removed.

In an exemplary design, the first circuit(s) in the forward path may comprise a complex summer, an upconverter, and a power amplifier, e.g., as shown in FIGS. 3 to 5. The complex summer (e.g., comprising real summers 326a and 326b) may subtract the rotated feedback signal from the input signal and may provide a compensated signal. The upconverter may upconvert the compensated signal and provide an upconverted signal. The power amplifier may amplify the upconverted signal and provide the output signal. The forward path may also comprise other circuits.

In an exemplary design, the second circuit(s) in the feedback path may comprise a downconverter, a filter, and a phase shift compensator, e.g., as shown in FIGS. 3 to 5. The downconverter may downconvert the output signal and provide a downconverted signal. The filter (e.g., comprising real filters 354a and 354b) may filter the downconverted signal and provide the feedback signal. The phase shift compensator may rotate the feedback signal and provide the rotated feedback signal. In an exemplary design, the phase shift compensator may comprise a complex multiplier that multiplies the feedback signal with a phase estimate signal and provides the rotated feedback signal. The phase estimate signal may comprise an estimate of the phase shift.

The feedback system may further comprise a phase shift estimator to estimate the phase shift. The phase shift estimator may receive the input signal and I and/or Q component of the feedback signal and may provide the phase estimate signal. In an exemplary design, the phase shift estimator may comprise first and second mixers and first and second filters. The first mixer (e.g., mixer 372a in FIG. 3) may mix a first (e.g., I or Q) component of the feedback signal with an I component of the input signal and may provide a first intermediate signal. The second mixer (e.g., mixer 372b) may mix the first component of the feedback signal with a Q component of the input signal and may provide a second intermediate signal. The first filter (e.g., integrator/filter 374a) may filter the first intermediate signal and provide an I component of the phase estimate signal. The second filter (e.g., integrator/filter 374b) may filter the second intermediate signal and provide a Q component of the phase estimate signal.

In another exemplary design, the phase shift estimator may further comprise third and fourth mixers and first and second summers. The third mixer (e.g., mixer 382c in FIG. 5) may mix a second (e.g., Q or I) component of the feedback signal with the I component of the input signal and may provide a third intermediate signal. The fourth mixer (e.g., mixer 382d) may mix the second component of the feedback signal with the Q component of the input signal and may provide a fourth intermediate signal. The first summer may combine (e.g., add) the first and fourth intermediate signals and may provide a first combined signal. The second summer may combine (e.g., subtract) the second and third intermediate signals and may provide a second combined signal. The first and second filters may then filter the first and second combined signals, respectively (instead of the first and second intermediate signals) and may provide the I and Q components of the phase estimate signal.

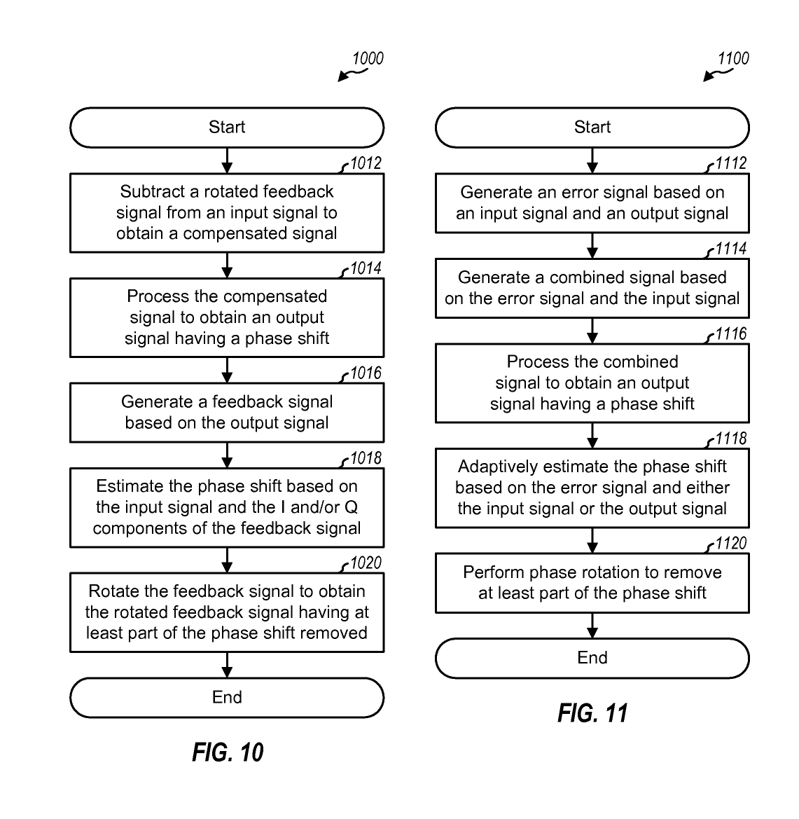

FIG. 10 shows an exemplary design of a process 1000 for generating an output signal with feedback and phase compensation. A rotated feedback signal may be subtracted from an input signal to obtain a compensated signal (block 1012). The compensated signal may be processed (e.g., upconverted and amplified) to obtain an output signal having a phase shift (block 1014). A feedback signal may be generated based on the output signal, e.g., by downconverting the output signal and filtering the downconverted signal (block 1016). The phase shift may be estimated based on the input signal and the I and/or Q components of the feedback signal (block 1018). The feedback signal may be rotated based on the estimated phase shift to obtain the rotated feedback signal having at least part of the phase shift removed (block 1020).

In another exemplary design, an apparatus may comprise a feedback system that may include a forward path and a feedback loop, e.g., as shown in FIGS. 7A to 7C. The forward path may include at least one first circuit that receives a combined signal and provides an output signal having a phase shift due to delay of one or more circuits. The first circuit(s) in the forward path may comprise a power amplifier, or an upconverter and a power amplifier, or some other circuit or combination of circuits. The feedback loop may comprise the first circuit(s) in the forward path as well as at least one second circuit. The second circuit(s) may generate an error signal based on an input signal and the output signal, generate the combined signal for the forward path based on the error signal and the input signal, and perform phase rotation to remove at least part of the phase shift.

In an exemplary design, the second circuit(s) in the feedback loop may comprise first and second summers, a loop filter, and a phase/gain compensator. The first summer may subtract a version (e.g., a downconverted version) of the output signal from a version of the input signal and may provide the error signal. The loop filter may filter the error signal to obtain a filtered error signal. The second summer may sum the filtered error signal with the input signal and may provide the combined signal.

The phase/gain compensator may perform phase rotation to remove at least part of the phase shift and may be located in the forward path (e.g., as shown in FIG. 7A) or a feedback path (e.g., as shown in FIG. 7B) within the feedback loop. The phase/gain compensator may adaptively estimate the phase shift based on the error signal and either the input signal or the output signal. In an exemplary design, the phase/gain compensator may multiply the error signal with a version of either the input signal or the output signal to obtain an intermediate signal, scale the intermediate signal with a scaling factor to obtain a scaled signal, and filter the scaled signal to obtain a complex value comprising an estimate of the phase shift, e.g., as shown in FIG. 8. In an exemplary design, the phase/gain compensator may perform phase rotation based on the estimated phase shift. In another exemplary design, the phase/gain compensator may perform phase rotation to remove at least part of the phase shift and may further perform gain compensation for the first circuit(s).

The feedback system may further comprise a model circuit that may implement a target function for the first circuit(s). The model circuit may receive the input signal and provide a target signal. The error signal may be generated based on the target signal and the output signal.

FIG. 11 shows an exemplary design of a process 1100 for generating an output signal with feedback and phase compensation. An error signal may be generated based on an input signal and an output signal (block 1112). For block 1112, the output signal may be downconverted and filtered to obtain a feedback signal. The feedback signal may then be subtracted from a version of the input signal to obtain the error signal, e.g., as shown in FIG. 9. A combined signal may be generated based on the error signal and the input signal (block 1114). In one exemplary design, the error signal may be filtered to obtain a filtered error signal, which may then be summed with the input signal to obtain the combined signal. The combined signal may be processed (e.g., upconverted and amplified) to obtain an output signal having a phase shift (block 1116). The phase shift may be adaptively estimated based on the error signal and either the input signal or the output signal (block 1118). Phase rotation may be performed (e.g., on any signal within a feedback loop) to remove at least part of the phase shift (block 1120).

The feedback system with phase compensation described herein may be implemented on one or more ICs, analog ICs, RF ICs (RFICs), mixed-signal ICs, application specific integrated circuits (ASICs), printed circuit boards (PCBs), electronics devices, etc. The feedback system with phase compensation may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), etc.

An apparatus implementing the feedback system with phase compensation described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a feedback system comprising
a forward path comprising at least one first circuit receiving an input signal and a rotated feedback signal and providing an output signal having a phase shift due to delay of one or more of the at least one first circuit, and
a feedback path comprising at least one second circuit receiving the output signal, generating a feedback signal, and rotating the feedback signal to obtain the rotated feedback signal having at least part of the phase shift removed.

2. The apparatus of claim 1, the at least one first circuit in the forward path comprising
a complex summer subtracting the rotated feedback signal from the input signal and providing a compensated signal,
an upconverter upconverting the compensated signal and providing an upconverted signal, and
a power amplifier amplifying the upconverted signal and providing the output signal.

3. The apparatus of claim 1, the at least one second circuit in the feedback path comprising
a downconverter downconverting the output signal and providing a downconverted signal,
a filter filtering the downconverted signal and providing the feedback signal, and
a phase shift compensator rotating the feedback signal and providing the rotated feedback signal.

4. The apparatus of claim 3, the phase shift compensator comprising a complex multiplier multiplying the feedback signal with a phase estimate signal and providing the rotated feedback signal, the phase estimate signal comprising an estimate of the phase shift.

5. The apparatus of claim 1, the feedback system further comprising
a phase shift estimator receiving the input signal and an inphase (I) component, or a quadrature (Q) component, or both the I and Q components of the feedback signal and providing a phase estimate signal comprising an estimate of the phase shift.

6. The apparatus of claim 5, the phase shift estimator comprising
a first mixer mixing a first component of the feedback signal with an I component of the input signal and providing a first intermediate signal, the first component being an I component or a Q component,
a second mixer mixing the first component of the feedback signal with a Q component of the input signal and providing a second intermediate signal,
a first filter filtering the first intermediate signal and providing an I component of the phase estimate signal, and
a second filter filtering the second intermediate signal and providing an Q component of the phase estimate signal.

7. The apparatus of claim 6, the phase shift estimator further comprising
a third mixer mixing a second component of the feedback signal with the I component of the input signal and providing a third intermediate signal, the second component being different from the first component,
a fourth mixer mixing the second component of the feedback signal with the Q component of the input signal and providing a fourth intermediate signal,
a first summer combining the first and fourth intermediate signals and providing a first combined signal, and
a second summer combining the second and third intermediate signals and providing a second combined signal,
the first filter filtering the first combined signal and providing the I component of the phase estimate signal, and
the second filter filtering the second combined signal and providing the Q component of the phase estimate signal.

8. A method comprising:
subtracting a rotated feedback signal from an input signal to obtain a compensated signal;
processing the compensated signal to obtain an output signal having a phase shift;
generating a feedback signal based on the output signal; and
rotating the feedback signal to obtain the rotated feedback signal having at least part of the phase shift removed.

9. The method of claim 8, further comprising:
estimating the phase shift based on the input signal and an inphase (I) component, or a quadrature (Q) component, or both the I and Q components of the feedback signal.

10. The method of claim 8, the processing the compensated signal comprising upconverting the compensated signal to obtain an upconverted signal, and amplifying the upconverted signal to obtain the output signal, and the generating the feedback signal comprising downconverting the output signal to obtain a downconverted signal, and filtering the downconverted signal to obtain the feedback signal.

11. An apparatus comprising:
means for subtracting a rotated feedback signal from an input signal to obtain a compensated signal;
means for processing the compensated signal to obtain an output signal having a phase shift;
means for generating a feedback signal based on the output signal; and
means for rotating the feedback signal to obtain the rotated feedback signal having at least part of the phase shift removed.

12. The apparatus of claim 11, further comprising:
means for estimating the phase shift based on the input signal and an inphase (I) component, or a quadrature (Q) component, or both the I and Q components of the feedback signal.

13. An apparatus comprising:
a feedback system comprising
a forward path including at least one first circuit receiving a combined signal and providing an output signal having a phase shift due to delay of one or more of the at least one first circuit, and
a feedback loop comprising the at least one first circuit in the forward path and at least one second circuit generating an error signal based on an input signal and the output signal, generating the combined signal for the forward path based on the error signal and the input signal, and performing phase rotation to remove at least part of the phase shift.

14. The apparatus of claim 13, the at least one first circuit in the forward path comprising a power amplifier.

15. The apparatus of claim 13, the at least one first circuit in the forward path comprising an upconverter and a power amplifier.

16. The apparatus of claim 15, the at least one second circuit in the feedback loop comprising
a downconverter downconverting the output signal from the power amplifier and providing a downconverted signal,
a filter filtering the downconverted signal and providing a feedback signal,
a summer subtracting the feedback signal from a version of the input signal and providing the error signal, and
a loop filter filtering the error signal to obtain a filtered error signal, the combined signal for the forward path being generated based on the filtered error signal and the input signal.

17. The apparatus of claim 13, the at least one second circuit in the feedback loop comprising
a summer subtracting a version of the output signal from a version of the input signal and providing the error signal, and
a loop filter filtering the error signal to obtain a filtered error signal, the combined signal for the forward path being generated based on the filtered error signal and the input signal.

18. The apparatus of claim 17, the at least one second circuit in the feedback loop further comprising
a second summer summing the filtered error signal with the input signal and providing the combined signal.

19. The apparatus of claim 13, the at least one second circuit in the feedback loop comprising
a phase compensator performing phase rotation to remove at least part of the phase shift, the phase compensator being located in the forward path or a feedback path within the feedback loop.

20. The apparatus of claim 19, the phase compensator estimating the phase shift and performing phase rotation based on the estimated phase shift.

21. The apparatus of claim 20, the phase compensator adaptively estimating the phase shift based on the error signal and either the input signal or the output signal.

22. The apparatus of claim 20, the phase compensator multiplying the error signal with a version of either the input signal or the output signal to obtain an intermediate signal, scaling the intermediate signal with a scaling factor to obtain a scaled signal, and filtering the scaled signal to obtain a complex value comprising an estimate of the phase shift.

23. The apparatus of claim 13, the at least one second circuit in the feedback loop comprising
a phase and gain compensator performing phase rotation to remove at least part of the phase shift and further performing gain compensation for the at least one first circuit, the phase and gain compensator being located in the forward path or a feedback path within the feedback loop.

24. The apparatus of claim 13, the feedback system further comprising
a model circuit implementing a target function for the at least one first circuit and receiving the input signal and providing a target signal, the error signal being generated based on the target signal and the output signal.

25. A method comprising:
generating an error signal based on an input signal and an output signal;
generating a combined signal based on the error signal and the input signal;
processing the combined signal to obtain an output signal having a phase shift; and
performing phase rotation to remove at least part of the phase shift.

26. The method of claim 25, further comprising:
adaptively estimating the phase shift based on the error signal and either the input signal or the output signal.

27. The method of claim 25, the processing the combined signal comprising upconverting the combined signal to obtain an upconverted signal, and amplifying the upconverted signal to obtain the output signal, and the generating the error signal comprising downconverting the output signal to obtain a downconverted signal, filtering the downconverted signal to obtain a feedback signal, and subtracting the feedback signal from a version of the input signal to obtain the error signal.

28. The method of claim 25, the generating the combined signal comprising filtering the error signal to obtain a filtered error signal, and summing the filtered error signal and the input signal to obtain the combined signal, and the performing phase rotation comprising rotating the combined signal based on an estimate of the phase shift to obtain a compensated signal, the compensated signal being processed to obtain an output signal.

29. An apparatus comprising:
means for generating an error signal based on an input signal and an output signal;
means for generating a combined signal based on the error signal and the input signal;
means for processing the combined signal to obtain an output signal having a phase shift; and
means for performing phase rotation to remove at least part of the phase shift.

30. The apparatus of claim 29, further comprising:
means for adaptively estimating the phase shift based on the error signal and either the input signal or the output signal.
